(19) United States
(12) Patent Application Publication
(10) Pub. No.: US 2011/0203144 A1
(43) Pub. Date: Aug. 25, 2011

(54) ANIMAL TAG AND METHOD FOR MAKING SAME

(75) Inventors: Doran L. Junek, Cuba, KS (US); Robert R. Williams, Menomonie, WI (US)

(73) Assignee: ERIGINATE CORPORATION, LEROY, MN (US)

(21) Appl. No.: 12/810,591

(22) PCT Filed: Jan. 6, 2009
(86) PCT No.: PCT/US09/30216

§ 371 Date: Nov. 9, 2010

Related U.S. Application Data
(60) Provisional application No. 61/019,447, filed on Jan. 7, 2008.

(51) Int. Cl. A01K 11/00; G09F 3/00; B29C 65/14; H05K 13/00

(52) U.S. Cl. 40/300; 156/275.1

(57) ABSTRACT

An animal tag and methods for making an animal tag include a primary body of material (e.g., that includes a circuit holding portion and an animal attachment portion), a circuit assembly, and a cover configured to cover the circuit assembly. The cover is welded to the primary body of material using light radiation.

This application claims the benefit of U.S. Provisional Application No. 61/019,447, filed Jan. 7, 2008, which is incorporated by reference herein.

The present invention relates generally to animal tags. More particularly, the present invention pertains to animal tags used for tracking animals (e.g., identification ear tags for cattle) and methods for making such tags.

The use of animal tags (e.g., ear tags) for the purpose of identifying animals, such as, for example, cattle or hogs, is common. For example, one and two-piece ear tags have been used to assist farmers and ranchers in identifying their own livestock.

Many of such ear tags are usable in a radio frequency identification (RFID) system. However, the construction of ear tags used in such RFID systems are generally lacking in many ways. For example, such ear tags may not be able to withstand harsh agricultural environments (e.g., provide the necessary protection for circuitry of the ear tag used for electronic identification). Further, for example, such ear tags used for electronic identification, as well as for visual identification, may not be economically manufactured.

### SUMMARY

The disclosure herein relates generally to one or more embodiments of animal tags and methods of making animal tags.

In one embodiment, the animal tag may include a primary body of material including at least a circuit holding portion (e.g., a flat circuit holding portion) and an animal attachment portion (e.g., wherein the animal attachment portion is configured to be attached to an animal). At least one recess may be defined in the circuit holding portion (e.g., the material of the primary body defining the at least one recess may include plastic material that absorbs light radiation of at least a first weld wavelength). The animal tag may further include a circuit assembly (e.g., a flat circuit assembly) that includes at least an antenna to be received within the recess defined in the circuit holding portion of the primary body of material and a cover (e.g., a flat cover) configured to cover the circuit assembly received in the at least one recess defined in the circuit holding portion of the primary body of material (e.g., the cover may include a plastic material that is transmissive to light radiation of at least the first weld wavelength such that light radiation of at least the first weld wavelength can pass through the flat cover and be absorbed by the plastic material defining the at least one recess so as to join the cover and the plastic material defining the at least one recess to form a sealed cavity in which the circuit assembly is located).

In another embodiment, an animal tag may include a primary body of material including at least a circuit holding portion and an animal attachment portion (e.g., at least the circuit holding portion may include plastic material that absorbs light radiation of at least a first weld wavelength). The animal tag may further include a circuit assembly (e.g., a flat circuit assembly) including at least an antenna positioned adjacent the circuit holding portion and a cover configured to cover the circuit assembly (e.g., the cover may include a plastic material that is transmissive to light radiation of at least the first weld wavelength such that light radiation of at least the first weld wavelength can pass through the cover and be absorbed by the plastic material of the circuit holding portion so as to join the cover and the plastic material of the circuit holding portion to form a sealed cavity in which the circuit assembly is located).

Still further one embodiment of a method for making an animal tag may include providing a primary body of material including at least a circuit holding portion and an animal attachment portion (e.g., the animal attachment portion may be configured to be attached to an animal). At least one recess may be defined in the circuit holding portion, and the material of the primary body defining the at least one recess may include a plastic material that absorbs light radiation of at least a first weld wavelength. Further, the method may include positioning a circuit assembly that includes at least an antenna within the at least one recess defined in the circuit holding portion of the primary body of material and then providing a cover configured to cover the circuit assembly received in the at least one recess defined in the circuit holding portion of the primary body of material (e.g., the cover may include a plastic material that is transmissive to light radiation of at least the first weld wavelength). Still further, the method may include passing light radiation of at least the first weld wavelength through the cover to be absorbed by the material defining the at least one recess so as to join the cover and the plastic material defining the at least one recess to form a sealed cavity in which the circuit assembly is located.

Another method for making an animal tag may include providing a primary body of material including at least a circuit holding portion and an animal attachment portion (e.g., wherein at least the circuit holding portion may include plastic material that absorbs light radiation of at least a first weld wavelength). The method may further include locating a circuit assembly that includes at least an antenna adjacent the circuit holding portion and positioning a cover over the circuit assembly (e.g., the cover may include a plastic material that is transmissive to light radiation of at least the first weld wavelength). Further, the method may include passing light radiation of at least the first weld wavelength through at least portions of the cover to be absorbed by the plastic material of the circuit holding portion so as to join the cover and the circuit holding portion to form a sealed cavity in which the circuit assembly is located.

In one or more embodiments of the method or tag, the cover may be opaque and/or the first weld wavelength may be 980 nanometers.

Further, in one or more embodiments of the tag or method, the at least one recess may include a first recess in the circuit holding portion configured to receive the circuit assembly and include a second recess in the circuit holding portion corresponding to the shape of the cover. A sealing interface is provided between edge portions of the cover and the plastic material defining the at least one recess to provide the sealed cavity in which the circuit assembly is located.

Further, in one or more embodiments of the tag or method, the primary body of material may include a first side surface and a second side surface. The at least one recess may be defined in the first side surface to a predetermined depth and the cover is planar with the first side surface when the cover is joined with the plastic material defining the recess to form the sealed cavity in which the circuit assembly is positioned.

The above summary is not intended to describe each embodiment or every implementation of the present disclosure. Advantages, together with a more complete understanding hereof, will become apparent and appreciated by referring to the following detailed description and claims taken in conjunction with the accompanying drawings.

### BRIEF DESCRIPTION OF THE DRAWINGS

FIG. 1 shows a first side perspective view of one exemplary embodiment of an animal tag (e.g., an ear tag for cattle).

FIG. 2A shows an exploded view of the animal tag of FIG. 1 including the primary body of material of the tag (e.g., a plastic material) having at least one recess formed therein, a circuit assembly, and a cover.

FIG. 2B shows the exploded view of the animal tag of FIG. 2 further including a stud for use in attaching the tag to an animal.

FIG. 2C shows a sectional view of the stud of FIG. 2B engaged with a portion of the primary body of material of the tag for attachment of the tag to an animal.

FIG. 3 shows a second side perspective view of the animal tag of FIG. 1 (i.e., a view from the opposite side shown in FIG. 1) including text marking on the tag.

FIG. 4 shows a plan view of the second side of the animal tag shown in FIG. 3 including the text marking thereon.

FIG. 5A shows a plan view of the first side of the primary body of material of the tag having at least one recess formed therein as shown in FIG. 2, FIG. 5B shows a side view of the shorter side of the primary body of material of the animal tag, FIG. 5C shows a side view of the longer side of the primary body of material of the animal tag, and FIG. 5D shows a first side perspective view of the primary body of material of the animal tag of FIG. 2, respectively.

FIG. 6A shows a plan view of the first side of the animal tag as shown in FIG. 1, FIG. 6B shows a side view of the longer side of the animal tag, FIG. 6C shows a section view taken along line AA of FIG. 6A, FIG. 6D shows a detail view of Section B shown in FIG. 6C, and FIG. 6E shows a first side perspective view of the animal tag of FIG. 1, respectively.

FIG. 7A shows a plan view of the cover of the animal tag as shown in FIG. 2, FIG. 7B shows a side view of the shorter side of the cover, FIG. 7C shows a side view of the longer side of the cover, and FIG. 7D shows a perspective view of the cover, respectively.

FIG. 8 shows a flow diagram of a method of making an animal tag such as shown in FIG. 1.

The figures are rendered primarily for clarity and, as a result, are not necessarily drawn to scale.

### DETAILED DESCRIPTION OF EXEMPLARY EMBODIMENTS

In the following detailed description of illustrative embodiments, reference is made to the accompanying figures of the drawing which form a part hereof, and in which are shown, by way of illustration, specific embodiments which may be practiced. It is to be understood that other embodiments may be utilized and structural changes may be made without departing from the scope of the disclosure.

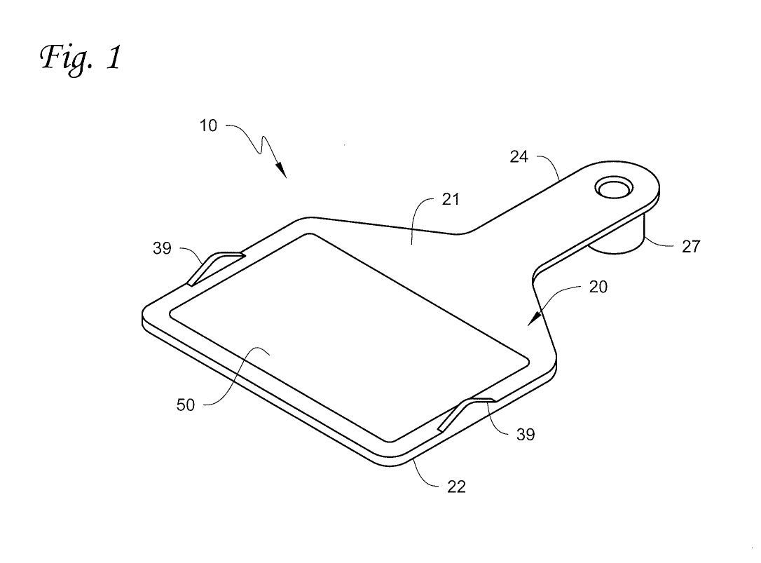

One or more embodiments of animal tags and methods of making animal tags are described with reference to FIGS. 1-8. For example, in one embodiment, such as shown in FIG. 1-7, an animal tag 10 (e.g., a radio frequency identification (RFID) ear tag for cattle) is provided. For example, the tag may be an ultra high frequency (UHF) ear tag for cattle. The tag may be designed for use, for example, in “speed of commerce” movement of animals and in auction barns (e.g., without need for infrastructure changes). Further, for example, the tag may be optimized for increased read distances from both the front and rear of the animal (e.g., the tags may be read from horseback, from an ATV, or in a sale ring). The animal tag (e.g., a livestock tag) may include features of a panel dangle tag design to allow visual identification, as well as, electronic identification. Further, at least in one embodiment, the tag is particularly suitable for harsh agriculture environments.

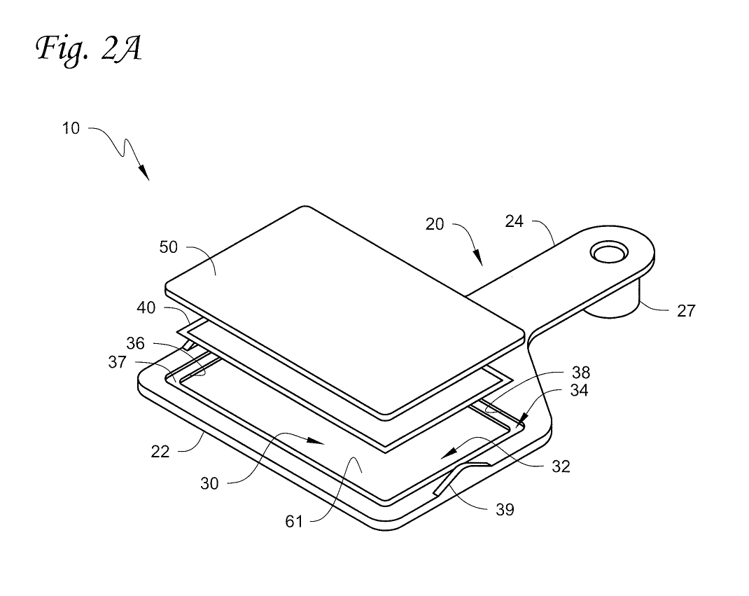

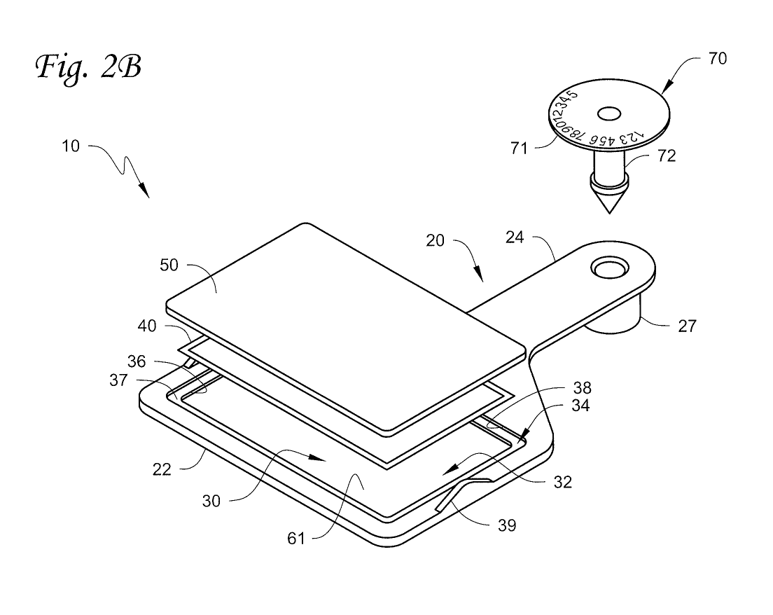

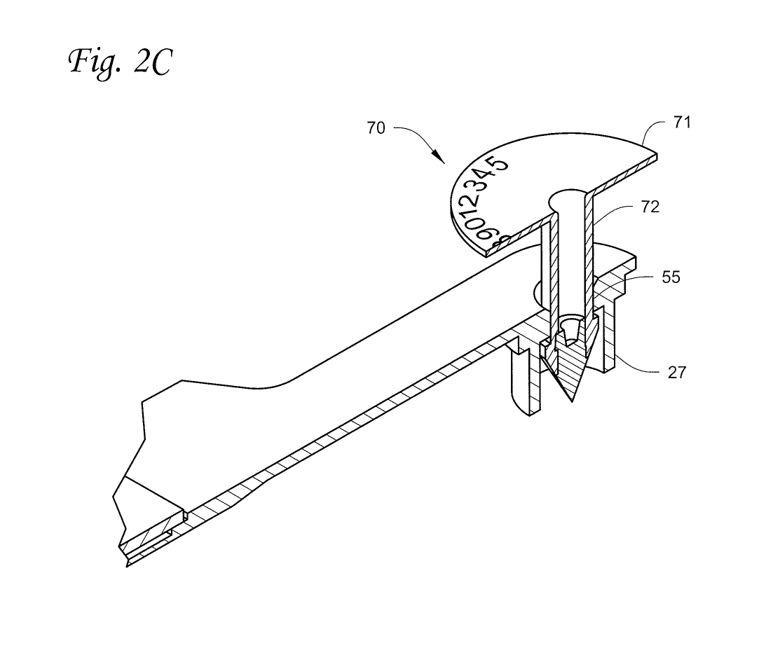

In the exemplary embodiment shown in FIGS. 1-7, the animal tag 10 includes a primary body of material 20 (e.g., a flat primary body of plastic material) that includes at least a circuit holding portion 22 and an animal attachment portion 24. The animal attachment portion 24 is configured to be attached to an animal. For example, one or more protrusions, appendages, extensions, or other elements for use in attaching the tag to an animal may be associated with the animal attachment portion 24. In one embodiment, at least one recess 30 (see FIG. 2) is defined in the circuit holding portion 22 and the material defining the at least one recess includes a plastic material that absorbs light radiation of at least a first weld wavelength (e.g., 980 nanometers).

The animal tag further includes a circuit assembly 40 (e.g., a flat circuit assembly). The flat circuit assembly 40 includes at least an antenna (not shown) to be received within the recess 30 defined in the circuit holding portion 22 of the primary body of material 20.

Still further, in one embodiment, the animal tag 10 includes a cover 50 (e.g., a flat cover) configured to cover the flat circuit assembly 40 received in the at least one recess 30 defined in the circuit holding portion 22 of the flat body of material 20. In one embodiment, the cover 50 is formed of a plastic material that is transmissive to light radiation of at least the first weld wavelength (e.g., 980 nanometers) such that light radiation of at least the first weld wavelength (e.g., 980 nanometers) can pass through the flat cover 50 and be absorbed by the material defining the at least one recess 30 so as to join the flat cover 50 and the plastic material 20 defining the at least one recess 30 to form a sealed cavity in which the flat circuit assembly 40 is located (e.g., forming a hermetically sealed cavity for the electrical components of the tag).

In one embodiment of the animal tag 10, the plastic material of the cover 50 (i.e., that is transmissive to light radiation of at least a first weld wavelength) is opaque. As used herein, opaque refers to a material that a user cannot see through. In other words, the opaque cover 50 prevents one to see the circuit assembly 40 when sealed in the cavity, but allows light radiation (e.g., 980 nanometers) necessary to weld the cover 50 in place to pass through the cover 50 and be absorbed by the plastic material defining the recess 30.

In another embodiment of the animal tag 10, the at least one recess 30 may include a first recess 32 defined in the circuit holding portion 22 configured to receive the flat circuit assembly 40 and a second recess 34 in the circuit holding portion 22 corresponding to the shape of the flat cover 50. For example, the first recess 32 may include an edge or side wall 36 that corresponds to the shape of the flat circuit assembly 40 (e.g., an edge that corresponds with the perimeter thereof) and the second recess 34 may include an edge or side wall 38 that corresponds to the shape of the cover 50 (e.g., an edge that corresponds to the perimeter thereof). As such, the flat circuit assembly 40 may be positioned in the first recess 32 adjacent the planar bottom 61 defining the recess 32 and the cover 50 can be positioned thereon in the second recess 34. A sealing interface portion between the flat cover 50 and the material defining the at least one recess (e.g., including ledge 37) is used to provide the sealed cavity in which the flat circuit assembly 40 is located.

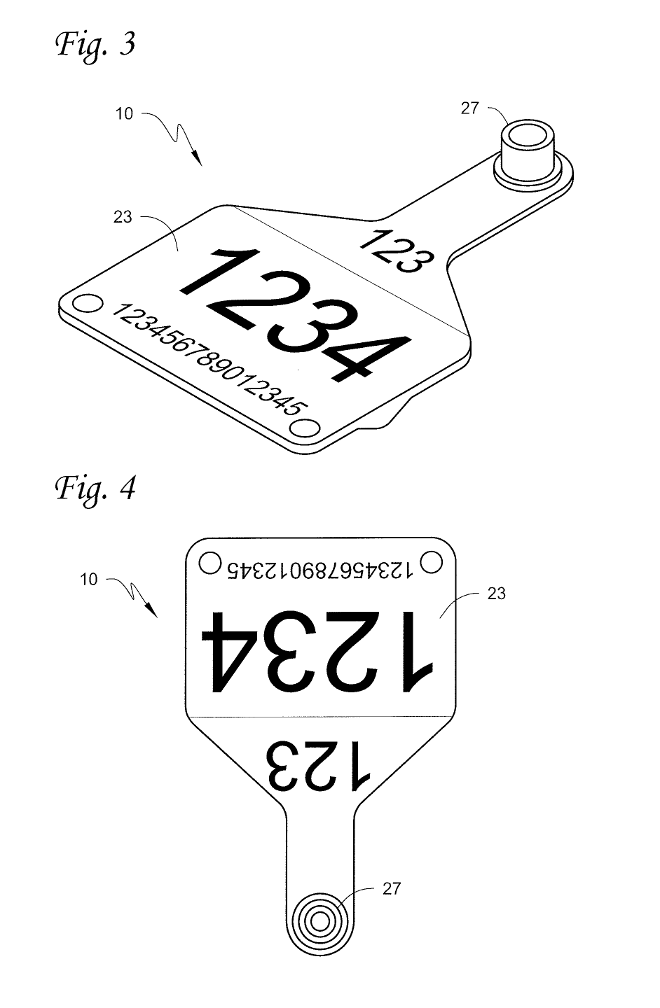

Yet further, in one or more embodiments, the flat primary body of material 20 may include a first side surface 21 (see FIG. 1) and a second side surface 23 (see FIG. 3). In such embodiments, one or more recesses may or may not be used. For example, in one or more embodiments, at least one recess 30 is defined in the first side surface 21 to a predetermined depth. The flat cover 50 is planar with the first side surface 21 when the flat cover 50 is joined with the plastic material defining the recess 30 to form the sealed cavity in which the flat circuit assembly 40 is positioned.

Further, for example, in another embodiment of the animal tag, the animal tag includes a primary body of material (e.g., a flat body of plastic material), a circuit assembly (e.g., a flat circuit assembly), and a cover (e.g., a flat cover). The flat body of material includes at least a circuit holding portion and an animal attachment portion. The animal attachment portion is configured to be attached to an animal and at least a portion of the circuit holding portion is formed of plastic material that absorbs light radiation of at least a first weld wavelength (e.g., 980 nanometers). The flat circuit assembly includes at least an antenna positioned adjacent the circuit holding portion (e.g., either within a recess or just adjacent a surface of the circuit holding portion). The cover may be configured to cover the flat circuit assembly (e.g., either configured to be positioned in a recess or just adjacent the circuit assembly), and formed of a plastic material that is transmissive to light radiation of at least the first weld wavelength such that light radiation of at least the first weld wavelength can pass through the flat cover (e.g., which may also be opaque) and be absorbed by the flat body of plastic material so as to join the flat cover and the plastic material of the circuit holding portion to form a sealed cavity in which the flat circuit assembly is located.

In other words, for example, recesses in the primary body of material need not be used. For example, the primary body of material, the circuit assembly, and a cover may be positioned adjacent each other (e.g., with the circuit assembly sandwiched between the primary body of material and the cover). The sizing of the components would be such that light radiation of at least the first weld wavelength can pass through at least portions of the cover (e.g., which may also be opaque) and be absorbed by at least portions of the primary body of plastic material so as to join the cover and the plastic material of the circuit holding portion to form a sealed cavity in which the circuit assembly is located (e.g., the cover and the circuit holding portion sized larger than the circuit assembly).

As used herein, when components are positioned adjacent each other, they may or may not be in contact with each other. However, in one or more embodiments, one or more components may be in contact with each other.

Further, as used herein, when a component is referred to as flat, it is meant that the configuration of such a component is generally planar having a thickness. However, being flat does not exclude components that are generally planar but have small projections or deviations (e.g., small relative to the size of the component) from planarity. Further, even though the components may be flat (e.g., in a normal state), they may be elastic or capable of being flexed.

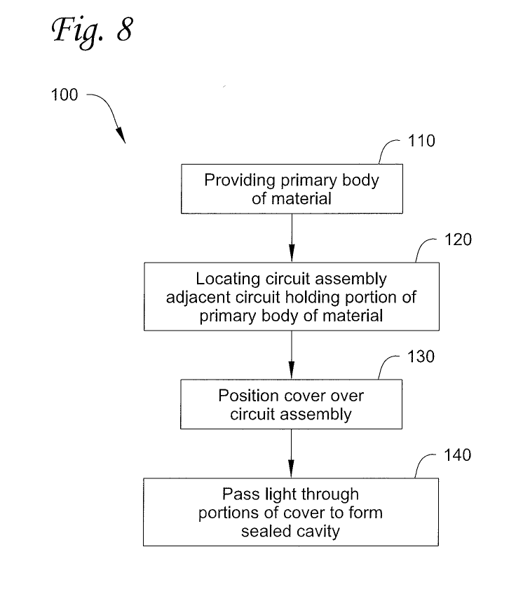

A method 100 for making an animal tag 10 according to at least one embodiment is shown in FIG. 8. For example, generally, the method 100 includes providing a primary body of material 20 (e.g., a flat primary body of plastic material) that includes at least a circuit holding portion 22 and an animal attachment portion 24 (block 110). The animal attachment portion 24 is configured to be attached to an animal.

The method 100 further includes locating a circuit assembly 40 (e.g., a flat circuit assembly 40) adjacent the circuit holding portion 22 of the primary body of material 20 (block 120). For example, in one embodiment, at least one recess 30 is defined in the circuit holding portion 22 (e.g., the material defining the at least one recess 30 may be plastic material that absorbs light radiation of at least a first weld wavelength). As such, the locating process may include positioning a flat circuit assembly 40 that includes at least an antenna within the at least one recess 30 defined in the circuit holding portion 22 of the flat body of material 20.

Thereafter, a cover 50 configured to cover the circuit assembly 40 (e.g., a flat circuit assembly) is provided and is positioned to cover the circuit assembly 40 (block 130). For example, a flat cover 50 may be configured to cover the flat circuit assembly 40 received in the at least one recess defined in the circuit holding portion 22 of the body of material 20 and may be position to cover the flat circuit assembly 40. The cover may be formed of a plastic material that is transmissive to light radiation of at least the first weld wavelength (e.g., it may also be opaque). One will recognize that recesses may be used to receive the cover and/or circuit assembly, but that other positioning of the components is possible (e.g., sandwiching of the circuit assembly between the cover and circuit holding portion).

Still further, as shown in block 140, the method 100 includes passing light radiation of at least the first weld wavelength (e.g., 980 nanometers) through the cover 50 to be absorbed by the material of the primary body (e.g., defining the at least one recess 30) so as to join the cover 50 and the plastic material of the primary body 20 to form a sealed cavity in which the circuit assembly 40 is located (e.g., to join the flat cover 50 and the plastic material 20 defining the at least recess 30 to form a sealed cavity in which the flat circuit assembly 40 is located).

In another embodiment of the method for making an animal tag (e.g., where a recess may or may not be used), the method includes providing a body of material (e.g., at least portions thereof foamed of plastic material) that includes at least a circuit holding portion and an animal attachment portion. The animal attachment portion is configured to be attached to an animal and the plastic material absorbs light radiation of at least a first weld wavelength. A circuit assembly that includes at least an antenna is positioned adjacent the circuit holding portion of the body of material and a cover configured to cover the flat circuit assembly is provided. At least portions of the cover may be formed of a plastic material that is transmissive to light radiation of at least the first weld wavelength. Light radiation of the first weld wavelength is passed through at least portions of the flat cover to be absorbed by the plastic material of the circuit holding portion so as to join the flat cover and the plastic material of the circuit holding portion to form a sealed cavity in which the flat circuit assembly is located.

The animal tags described herein may use any suitable circuit such as one that operates in the ultra high frequency (UHF) spectrum. However, any suitable structural configuration for the circuit assembly may be used (e.g., the shape need not be flat if the other components are sized to accommodate a non-flat configuration, such as a folded circuit, a more three-dimensional circuit, etc.). Further, any spectrum usage is also contemplated although some portions of the frequency spectrum may be beneficial over others.

A challenge to, for example, the beef industry has been the international crisis resulting from identification of BSE (Mad Cow Disease) as a public health threat and the associated economic impact to the industry. Various systems are available that can use an ear tag such as described herein. For example, the following is a brief overview of the collection of information using an Ultra High Frequency (UHF) Electronic Product Code (EPC) Global ear tag as a part of the system. For example, the animal identification system may be designed to the USDA's National Animal Identification System (NAIS) performance specifications. It can provide “speed of commerce” information collection and management for animal trace-back and trace-forward with verification of premise registration and herd contact.

The system may include collection methods from a variety of sources with RFID at the center of the development. The UHF RFID tag (e.g., such as provided in a configuration described herein) addresses a desire to tag millions of cattle as a part of the NAIS. In addition, the system may include distributed access controlled databases with data privacy and defense-in-depth Information Security (INFOSEC). The architecture may provide Communications Security (COMSEC) and user defined rules based operations software all as an integrated multi-region system. The system may greatly improve safety and security of the nation's beef supply through source verification while enabling electronic commerce for value added animal product branding for programs such as “natural beef”.

Medium Range High Capacity Animal Identification may also be assisted through use of a tag provided using a configuration as described herein. The Radio Frequency Identification (RFID) problem that has eluded the cattle industry is how to collect information from an ear tag at distances up to 15 feet without impact to the current processes of trading cattle (e.g., it must not slow the cattle trade down in high capacity fast moving operations such as sale barns).

Low Frequency (LF) tags and readers that serve a mostly stationary animal environment such as a dairy farm are available. Much of this current off-the-shelf equipment is reliable, cost effective and offers suitable options for the stationary operation configurations. However, in this industry nearly all currently available LF Radio Frequency Identification (RFID) systems must funnel cattle through 3-foot wide “pinch points” in order that their low frequency RFID tags can be read at a close range within 18 inches.

Even with pinch points, reliability is usually very low and extraordinarily costly measures are often needed to bring the accuracy level to 95%, which is unacceptable. With a UHF ear tag, provided in a configuration as described herein, coupled to low-cost commercially available RFID collection equipment, pinch points are eliminated and cattle can flow unimpeded through 15-foot wide alleys in high traffic areas such as sale barns and processing plants.

An Ultra High Frequency (UHF)-EPC global Ear Tag does not delay the animal trade process. Such a tag may allow large numbers of animals to be identified while being processed through alleyways in a normal large herd operation without delay. It easily supports the trading of thousands of animals a day at a single site. The collection equipment configuration may include passive ear tags, antennas, readers, rugged computers and cabling.

For example, a system may include side and top firing antennas. In operation, the Radio Frequency Identification (RFID) “reader” antenna emits radio waves (like radio or TV signals) to energize the tag as it passes through the alleyway or gantry. The tag responds with a unique signal that the reader recognizes and sends to a computer to log into a database system for distribution and retrieval. For example, a handheld reader such as a Motorola MC9090-G RFID reader may be used, a fixed reader such as a Sirit Identity 5100 reader may be used, or any other suitable reader may be used compatible with the circuit assembly. For example, a handheld reader may have a range of up to 15 feet and a fixed reader may have a range of 25 feet or more.

The Ultra High Frequency (UHF, 915 MHz band) tag, such as one or more animal tag embodiments described herein, may be based on the Electronic Product Code (EPC, American) standard. This technology is newer but only slightly more expensive than the ISO Low Frequency (LF) products available. However, it has an effective medium read range of about 15 feet and can be read more often within the same amount of time greatly improving the ability to reliably collect information from a tag. If you load up and bring 100 calves in to trade at a sale barn then you want a technology that will count all 100 and not just 95 animals and without delay. For sale barns, processing plants and other operations where a sizable number of animals are herded quickly, sometimes 3-7 abreast, through alleys, in and out of trucks and holding pens the UHF tag offers the ability to identify and track animals without slowing the trading process down. The Sale Barn operation should not have to modify its' pen configuration or force animals into “pinch points” to accommodate the tag collection process. This technology also offers robust features to address environmental field conditions associated with weather and is also available with hand held readers.

In addition, the nature of the UHF frequency lends itself to smaller and lighter antennas, which are also currently available. It is also better suited to the animal trade operation due to limited bleed over reads from pen to pen. This means that when you want to read the animals in a first pen then you don't get reads from three pens down. However, this does not mean that a UHF system does not need to be “tuned” to eliminate the bleed over from an adjacent pen.

As such, the circuit assembly 40 (e.g., a flat circuit assembly) may include any circuitry necessary to carry out identification of an animal. In at least one embodiment, it is circuitry for providing a UHF animal tag (e.g., a UHF ear tag). For example, the passive circuit assembly may include an integrated circuit for storing and/or processing information, modulating and demodulating a signal and can also be used for other specialized functions. Further, the circuit assembly includes an antenna for receiving and transmitting the signal. However, one will recognize that any circuitry (e.g., passive or active) used for the purpose of carrying out identification or in the management of animals may be used. The particular type of antenna and/or configuration of the circuitry may vary and is not to be taken as limiting to the present invention.

In one embodiment, the flat circuit assembly includes copper flake material screen printed on a mylar/polyester substrate. Upon completion of screen printing the antennae, a silicon chip (e.g., an integrated circuit) may be sonic welded to complete the UHF inlay design. At least in one embodiment, the electronic inlay is kept flat as any distortion or curvature of the inlay may affect the tuning and performance of the inlay. At least in one embodiment, the substrate material assists to retain the inlay in a flat planar configuration. Even if slightly flexed, the tag returns to a state of being planar.

The various parts of the animal tag such as the cover 50 and primary body of material 20 may be provided in any manner. For example, such components of the animal tag may be provided by injection molding. Further, for example, such components may be provided by extrusion or any other suitable process.

The materials used to form the primary body of material 20 (e.g., the flat body of material) may be any plastic material that absorbs light radiation of a first weld wavelength (e.g., in the case of IRAM welding of plastic parts together, the weld wavelength may be 980 nanometers). For example, such plastic materials may be a polymer such as polyurethane. However, other suitable polymers such as acrylics, elastomers, polypropylene, high or low density polyethylene, nylon, or the like, may be used.

The plastic material that forms the cover 50 may be any plastic material that is transmissive to light radiation of the first weld wavelength (e.g., in the case of IRAM welding of plastic parts together, the weld wavelength may be 980 nanometers). Further, the plastic material that forms the cover may be and is preferably opaque so that the circuit assembly cannot be seen by a user. For example, such plastic materials may be a polymer such as polyurethane. However, other suitable polymers such as acrylics, elastomers, polypropylene, high or low density polyethylene, nylon, or the like, may be used.

In one embodiment, the plastic material of the primary body of material 20 and the cover 50 is flexible so as to allow the tag to bend, but thereafter return to its normal state (e.g., a planar shape). Further, the plastic material should be environmentally stable (e.g., at high and low temperatures).

The process used to join the primary body of material 20 and the cover 50 to form the hermetically sealed cavity in which the circuit assembly 40 is positioned may be a laser infrared assembly method (IRAM) process. The laser IRAM is based on the idea of passing light/laser radiation through one plastic component and providing the second component to absorb the laser light. This absorption results in heating and melting of the interface. For example, with the application of a controlled clamp force, the parts are joined. For example, in one embodiment, IRAM technology heats the entire welding surface (e.g., the ledge 37 defining the second recess 34) simultaneously as compared to heating a single spot and moving the IR spot across the welding zone. Laser IRAM welding processes are known and systems are available from Branson Ultrasonics Corporation (Danbury Conn.).

The IRAM process can essentially be described as a 360 degree laser welding process that delivers a hermetic seal. Other laser welding processes are not entirely reliable in making a hermetic seal. The plastic materials used to make this part are traditionally difficult to weld together. Some other processes are available that can bond the material (e.g., such as hot plate welding and spin welding), however, they are not well suited for the design of the ear tag described herein, nor would they be cost effective. For example, hot plate welding is too slow and spin welding needs round parts for the process to be effective. Antenna design may dictate the geometry of such a part which may eliminate usage of traditional welding process (e.g., the part is not round).

Typically, most plastic welding is done with a clear part and a black part to absorb the laser energy. The clear part allows the laser to pass through it to the black part, and the black part absorbs the laser energy to melt the surface to which the clear part bonds.

According to the present invention, the process works contrary to typical weld processes. An opaque part (e.g., the cover 50 such as a black cover) that you cannot see through is used, but this opaque part still allows the laser light at the weld wavelength to pass through it. The other plastic of the primary body 20 of the animal tag absorbs the energy to heat and melt the interface with the cover 50 and form a hermetic seal. Such plastic materials may be available from RTP Company (Winona, Minn.).

As such, at least in one embodiment, the cover 50 may be formed of a black plastic (e.g., formed using a black colorant in a polyether or thermoplastic polyurethane elastomer (such as Elastollan® 1185A10W from RTP, or BASF 1180A10)) that passes a wavelength of 980 nanometers through it. For example, about 40% to 70% of the wavelength may be freely transmitted through this black material.

In at least one embodiment, the IRAM welder operates at a wavelength of 980 nanometers. However, in one or more other embodiments, one or more different wavelengths may be effective for the IRAM welding. As one would recognize, the materials used in the components would need to be made effective for such a weld at the one or more different wavelengths (e.g., different chemistries or additives may be needed to make the component effective at the weld wavelength).

At least in one embodiment, the cover 50 is made of about 96% of the BASF Elastollan® 1185A10W material (or BASF 1180A10), and 4% of the black colorant that allows the laser to pass through, a UV stabilizer to protect against harmful sunlight rays, and a heat additive to protect against high temperature. The material can be provided in a pellet form that can be mixed at about 4 pounds per about 96 pounds of BASF Elastollan® 1185A10W material (or BASF 1180A10).

The laser absorbing primary body of plastic material 20 also needs an additive to absorb the laser energy and should be available in various colors (e.g., except, for example, black so that marking on it can be accomplished). As such, at least in one embodiment, laser absorbing materials are available as Clearweld® materials, a Gentex Corporation (Simpson, Pa.) technology. Such laser absorbing materials provide an additive that can be mixed with BASF Elastollan® 1185A10W material (or BASF 1180A10); again containing about 96% BASF and about 4% of the additive which has colorant (white, green, blue etc), UV additive, heat additive and the Clearweld® product. Once again, this can be provided in pellet form to be mixed at about 4 pounds per about 96 pounds of BASF Elastollan® 1185A10W (or BASF 1180A10). In one or more embodiments, a laser marking additive may be added to the materials described herein for laser marking purposes.

As shown in FIGS. 1 and 2, the animal attachment portion 24 of the primary body 20 of the animal tag 10 includes a stud receiving portion 27 and is functional with a stud 70 as shown in the sectional view of FIG. 2C. For example, the stud 70 includes a first flat portion 71 having a locking projection portion 72 extending orthogonal thereto. The locking projection portion 72 is configured for insertion into an opening 55 defined by the stud receiving portion 27 and includes one or more surfaces that function with one or more surfaces of the stud receiving portion to keep the stud 70 within the opening; resulting in attachment of the tag to an animal (e.g., an ear of an animal). Such attachment may be accomplished in various manners and the present invention is not limited to any particular attachment mechanism. For example, any type of male and female configured components that allow the tag to be attached to an animal may be used (e.g., functional with locking features, frictional fit features, or any other components that engage with one another). The disclosure herein is in no manner limited by the type of attachment components listed herein as many different configurations may be used to attach the tag to the animals (e.g., ear of cattle).

Further, as shown in FIG. 1, anti shingle tabs 39 are provided at the edges of the ear tag 10 to assist in automated assembly of the tag.

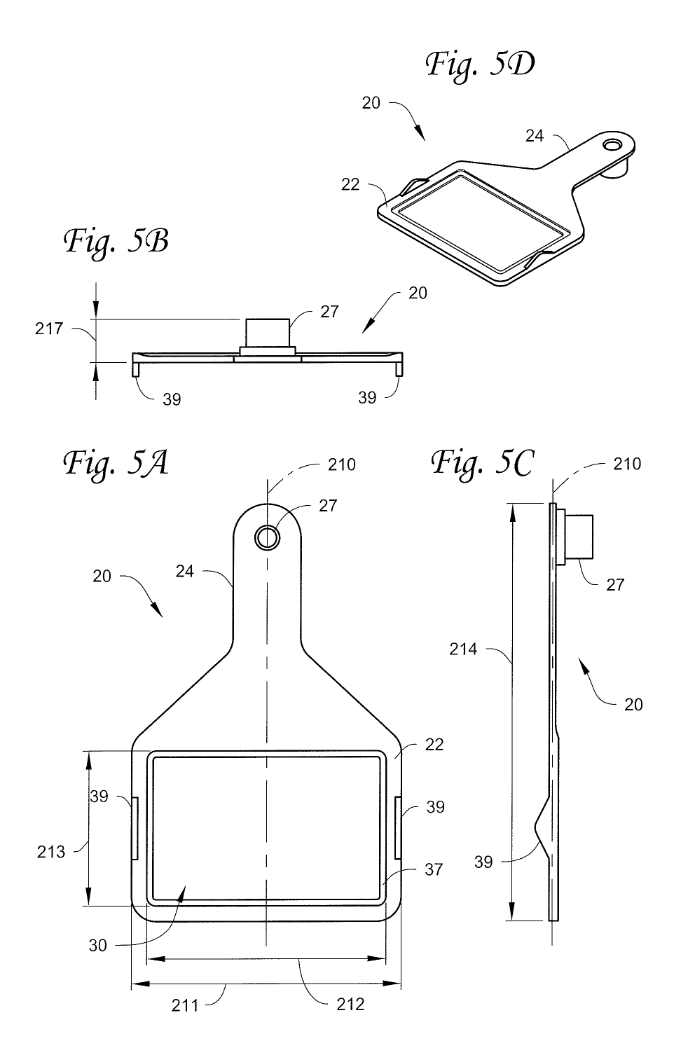

As shown in FIGS. 3 and 4, the animal tag 10 may be marked with text or any other graphic. For example, such marking may be performed by laser marking systems, such as, for example, a Cobra diode pumped laser marking system (e.g., YAG laser-Cobra II or any other such system) available from Electrox (Indianapolis, Ind.), or a laser marking system that includes a laser available from Panasonic. Such marking may correspond to the identification information contained by the circuit assembly. For example, the identification number of the animal may be printed on the tag and be able to be read from the electrical circuitry of the tag by a suitable system.

Further, at least in one embodiment, the circuit holding portion 22, the circuit assembly 40, and the cover 50, are all of a generally rectangular shape. The animal attachment portion 24 then extends therefrom and is reduced in width (e.g., a tapered, tab-like element, etc.). However, the present disclosure is not limited to any particular shape although some shapes may be more beneficial for the design of an antenna of the tag. For example, a rectangular portion of the tag may assist in holding the antennae configuration more effectively.

One or more embodiments of the primary body of material are shown in FIGS. 5A-5D. For example, FIG. 5A shows a plan view of the first side of the primary body of material 20 of the tag having at least one recess 30 formed therein, FIG. 5B shows a side view of the shorter side of the primary body of material 20 of the animal tag, FIG. 5C shows a side view of the longer side of the primary body of material 20 of the animal tag, and FIG. 5D shows a first side perspective view of the primary body of material 20 of the animal tag, respectively.

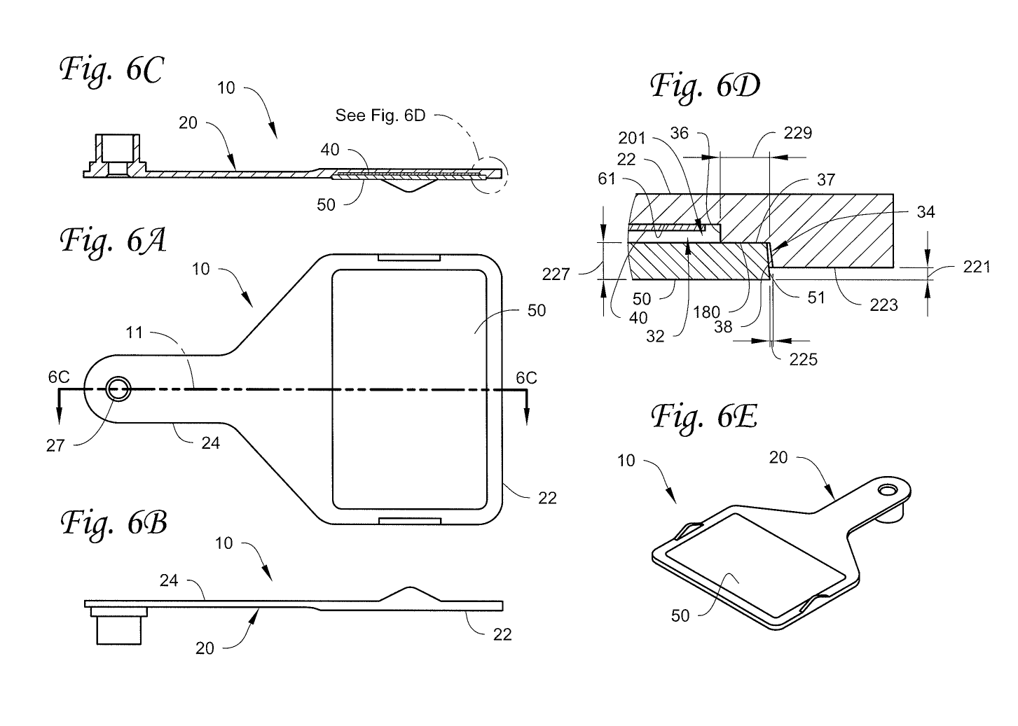

As shown in FIGS. 5A-5D, the primary body of material 20 includes the circuit holding portion 22 and the animal attachment portion 24 extending therefrom along an axis 210 of the primary body of material that, at least in one embodiment, coincides with the axis 11 of the animal tag 10 (see FIGS. 6A-6E). In one embodiment, the circuit holding portion 22 has a length 211 orthogonal to the axis 210 suitable to allow a recess 30 to be defined therein having a length 212 and a width 213 (i.e., in the direction of the axis 210). Further, as shown in the exemplary embodiment, the circuit holding portion 22 of the primary body of material 20 has a thickness suitable to allow for definition of at least one recess 30 therein configured to receive the circuit assembly 40 and/or a cover 50.

At least in one embodiment, the animal attachment portion 24 extending along an axis 210 provides a height 214 for animal tag 10 such that the information contained on or in the tag is away a predetermined distance from the animal on which it is used. Further, the height 217 of the stud receiving portion 27 orthogonal to the axis 210 is suitable for effectively receiving the stud 70 (see, for example, FIG. 2C) to attach the animal tag 10 to the animal.

One will recognize that, at least in one embodiment, the primary body of material 20 is generally flat in the area of the circuit holding portion 22. In another embodiment, the animal attachment portion 24 may take one of various configurations and need not be flat. Further, in other configurations of the primary body of material 20, the area of the circuit holding portion 22 is not flat but still allows for at least one recess 30 to be defined therein and/or the animal attachment portion 24 may be flat with suitable components for attachment to the animal.

Further, at least in one or more embodiments, at least certain portions of the primary body of material 20 are formed of plastic material to allow for a weld process to be carried out for providing a sealed cavity as described herein. For example, at least in one embodiment, at least the ledge 37 is formed of plastic material suitable to be used in a weld process as described herein. However, in other embodiments, substantially the entire primary body of material 20 may be formed of the same plastic material.

FIG. 6A shows a plan view of the first side of the animal tag 10 as shown in FIG. 1, FIG. 6B shows a side view of the longer side of the animal tag 10, FIG. 6C shows a section view taken along line AA of FIG. 6A, FIG. 6D shows a detail view of Section B shown in FIG. 6C, and FIG. 6E shows a first side perspective view of the animal tag 10 of FIG. 1, respectively.

As shown in the detail view of FIG. 6D, the first recess 32 and second recess 34 are defined in the circuit holding portion 22 of the primary body of material 20 by bottom surface 37 of first recess 32 and side wall 36 about the perimeter of the first recess 32. The depth of the first recess 32 accommodates receipt of the circuit assembly 40 (e.g., the circuit assembly may be attached to the bottom surface 37 of the first recess 32).

The second recess 34 is formed adjacent the first recess 32. For example, in one embodiment, the second recess 34 is defined by ledge 37 of the primary body of material 20 and side wall 38 about the perimeter of the second recess 34. The depth of the second recess 34 accommodates receipt of the cover 50 (e.g., the depth of the second recess 34 is approximately the same as the thickness 227 of the cover 50 so as to form a generally planar surface at the first side 21 of the animal tag 10). As used herein, a surface formed of multiple components may be generally planar even with a slight deviation of levels at the connection points of the components. For example, as shown in FIG. 6D, a slight rise 221 of the cover 50 relative to the perimeter surface 223 of the circuit holding portion 22 still results in a generally planar surface.

With the cover 50 fixedly attached to the ledge 37 (e.g., using IRAM processing), sealed cavity 201 is created (e.g., hermetically sealed cavity created by the sealing interface 180 between ledge 37 and edge regions of the cover 50). Such a sealed cavity 201 provides protection for the circuit assembly 40. The ledge 37 is a width 229 suitable for providing an effective sealing interface 180 with the cover 50, such as, when such components are welded together.

The circuit assembly 40 may be directly in contact with one or more surfaces defining the cavity 201 (e.g., bottom surface 37, cover 50, etc.) or there may be open gaps between the circuit assembly 40 and one or more surfaces defining the cavity 201 (e.g., gap between the circuit assembly 40 and the cover as shown in FIG. 6D, gap between the circuit assembly 40 and side wall 36 as shown in FIG. 6D, etc.).

Further, as described herein, certain openings or recesses may be configured for receiving one or more components therein. Generally, such openings or recesses are sized slightly larger than the component or components that are received in the openings or recesses. For example, at least in one embodiment as shown in FIG. 6D, the recess 34 is formed slightly larger than the cover 50 allowing the cover to effectively fit therein leaving a small gap 225 between the perimeter edge 51 of the cover 50 and the side wall 38 defining the second recess 34.

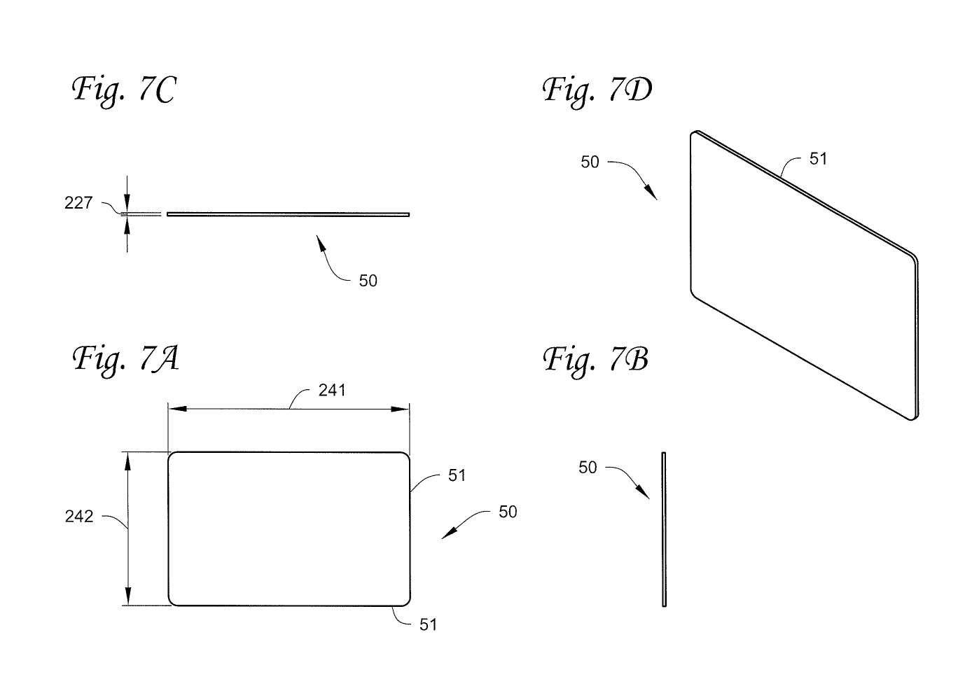

FIG. 7A shows a plan view of the cover 50 of the animal tag 10 as shown in FIG. 2, FIG. 7B shows a side view of the shorter side of the cover 50, FIG. 7C shows a side view of the longer side of the cover 50, and FIG. 7D shows a perspective view of the cover 50, respectively. The cover 50 is flat and has a width 242 and a length 241 that corresponds to the length 212 and width 213 of the second recess 38 such that it rests on ledge 37 defining the recess 38 when assembled.

All references cited herein are incorporated in their entirety as if each were incorporated separately. This invention has been described with reference to illustrative embodiments and is not meant to be construed in a limiting sense. Various modifications of the illustrative embodiments, as well as additional embodiments of the invention, will be apparent to persons skilled in the art upon reference to this description. Accordingly, the invention is to be limited only by the claims provided below and equivalents thereof.

What is claimed is:

1. An animal tag comprising:
a primary body of material comprising at least a circuit holding portion and an animal attachment portion, wherein the animal attachment portion is configured to be attached to an animal, wherein at least one recess is defined in the circuit holding portion, and further wherein the material of the primary body defining the at least one recess comprises plastic material that absorbs light radiation of at least a first weld wavelength;
a circuit assembly comprising at least an antenna to be received within the recess defined in the circuit holding portion of the primary body of material; and
a cover configured to cover the circuit assembly received in the at least one recess defined in the circuit holding portion of the primary body of material, wherein the cover comprises a plastic material that is transmissive to light radiation of at least the first weld wavelength such that light radiation of at least the first weld wavelength can pass through the flat cover and be absorbed by the plastic material defining the at least one recess so as to join the cover and the plastic material defining the at least one recess to form a sealed cavity in which the circuit assembly is located.

2. The animal tag of claim 1, wherein the plastic material of the cover that is transmissive to light radiation of at least the first weld wavelength is opaque.

3. The animal tag of claim 1, wherein the first weld wavelength is 980 nanometers.

4. The animal tag of claim 1, wherein the at least one recess comprises a first recess in the circuit holding portion configured to receive the circuit assembly and comprises a second recess in the circuit holding portion corresponding to the shape of the cover, and further wherein a sealing interface between edge portions of the cover and the plastic material defining the at least one recess is used to provide the sealed cavity in which the circuit assembly is located.

5. The animal tag of claim 1, wherein the primary body of material comprises a first side surface and a second side surface, wherein the at least one recess is defined in the first side surface to a predetermined depth, wherein the cover is planar with the first side surface when the cover is joined with the plastic material defining the recess to form the sealed cavity in which the circuit assembly is positioned.

6. The animal tag of claim 1, wherein the circuit assembly comprises a flat circuit assembly, and cover comprises a flat cover, wherein the flat circuit assembly and the flat cover are configured to be received within the at least one recess.

7. An animal tag comprising:
a primary body of material comprising at least a circuit holding portion and an animal attachment portion, wherein the animal attachment portion is configured to be attached to an animal, wherein at least the circuit holding portion comprises plastic material that absorbs light radiation of at least a first weld wavelength;
a circuit assembly comprising at least an antenna positioned adjacent the circuit holding portion; and
a cover configured to cover the circuit assembly, wherein the cover comprises a plastic material that is transmissive to light radiation of at least the first weld wavelength such that light radiation of at least the first weld wavelength can pass through the cover and be absorbed by the plastic material of the circuit holding portion so as to join the cover and the plastic material of the circuit holding portion to form a sealed cavity in which the circuit assembly is located.

8. The animal tag of claim 7, wherein the cover is opaque.

9. The animal tag of claim 7, wherein the first weld wavelength is 980 nanometers.

10. The animal tag of claim 7, wherein the circuit assembly comprises a flat circuit assembly, and further wherein the cover comprises a flat cover, wherein the flat circuit assembly and the flat cover are configured to be received within the at least one recess.

11. A method for making an animal tag, the method comprising:
providing a primary body of material comprising at least a circuit holding portion and an animal attachment portion, wherein the animal attachment portion is configured to be attached to an animal, wherein at least one recess is defined in the circuit holding portion, and further wherein the material of the primary body defining the at least one recess comprises plastic material that absorbs light radiation of at least a first weld wavelength;
positioning a circuit assembly comprising at least an antenna within the at least one recess defined in the circuit holding portion of the primary body of material;
providing a cover configured to cover the circuit assembly received in the at least one recess defined in the circuit holding portion of the primary body of material, wherein the cover comprises a plastic material that is transmissive to light radiation of at least the first weld wavelength; and
passing light radiation of at least the first weld wavelength through the cover to be absorbed by the material defining the at least one recess so as to join the cover and the plastic material defining the at least one recess to form a sealed cavity in which the circuit assembly is located.

12. The method of claim 11, wherein the cover is opaque.

13. The method of claim 11, wherein the first weld wavelength is 980 nanometers.

14. The method of claim 11, wherein the at least one recess comprises a first recess in the circuit holding portion configured to receive the circuit assembly and comprises a second recess in the circuit holding portion corresponding to the shape of the cover, and further wherein a sealing interface between edge portions of the cover and the material defining the at least one recess is used to provide the sealed cavity in which the circuit assembly is located.

15. The method of claim 11, wherein the primary body of material comprises a first side surface and a second side surface, wherein the at least one recess is defined in the first side surface to a predetermined depth, wherein the cover is planar with the first side surface when the cover is joined with the plastic material defining the recess to form the sealed cavity in which the circuit assembly is positioned.

16. The method of claim 11, wherein the circuit assembly comprises a flat circuit assembly, and further wherein the cover comprises a flat cover, wherein the flat circuit assembly and the flat cover are configured to be received within the at least one recess.

17. A method for making an animal tag, the method comprising:
providing a primary body of material comprising at least a circuit holding portion and an animal attachment portion, wherein the animal attachment portion is configured to be attached to an animal, wherein at least the circuit holding portion comprises plastic material that absorbs light radiation of at least a first weld wavelength;
locating a circuit assembly comprising at least an antenna adjacent the circuit holding portion;
positioning a cover over the circuit assembly, wherein the cover comprises a plastic material that is transmissive to light radiation of at least the first weld wavelength; and
passing light radiation of at least the first weld wavelength through at least portions of the cover to be absorbed by the plastic material of the circuit holding portion so as to join the cover and the circuit holding portion to form a sealed cavity in which the circuit assembly is located.

18. The method of claim 17, wherein the cover is opaque.

19. The method of claim 17, wherein the first weld wavelength is 980 nanometers.

20. The method of claim 17, wherein the circuit assembly comprises a flat circuit assembly, and further wherein the cover comprises a flat cover, wherein the flat circuit assembly and the flat cover are configured to be received within the at least one recess.
